(19) United States
(12) Patent Application Publication
(10) Pub. No.: US 2026/0324035 A1
(43) Pub. Date: Oct. 15, 2026

(54) P-GAN HIGH ELECTRON MOBILITY TRANSISTOR FIELD PLATING

(71) Applicant: VISHAY SILICONIX LLC, San Jose, CA (US)

(72) Inventors: Ayman SHIBIB, San Jose, CA (US); Saba RAJABI, San Francisco, CA (US)

(73) Assignee: VISHAY SILICONIX LLC, San Jose, CA (US)

(21) Appl. No.: 19/100,411

(22) PCT Filed: Aug. 3, 2022
(86) PCT No.: PCT/US2022/039314

§ 371 Date: Jan. 31, 2025

(51) Int. Cl. H10D 64/00; H10D 30/01; H10D 30/47; H10D 62/10; H10D 62/60; H10D 62/85; H10D 62/852

(52) U.S. Cl. CPC H10D 64/112; H10D 30/015; H10D 30/474; H10D 62/60; H10D 62/8503; H10D 62/852; H10D 62/102

(57) ABSTRACT

A high electron mobility transistor (HEMT) which includes a source disposed on a surface, a drain disposed on the surface, a gate disposed on the surface between the source and the drain, and a first field plate disposed on the surface between the gate and the drain. In some implementations, the first field plate includes a p-type doped GaN (P-GAN). In some implementations, the first field plate includes a doping concentration, doping material, geometry, and/or position that is configured to minimize an increase of an on-resistance of the HEMT. In some implementations, the first field plate extends continuously between and parallel to the source and the drain regions, such that any path from the source to the drain passes under, through, or over the first field plate. In some implementations, the first field plate extends continuously beyond an entire width of the surface between the source and the drain.

### FIELD OF THE INVENTION

The present disclosure relates to transistor devices, and is more particularly related to field plating for high electron mobility transistor (HEMT) devices.

### BACKGROUND

A HEMT is a field effect transistor (FET) that incorporates a junction between two materials with different band gaps as a channel. Such junctions may be referred to as heterojunctions, and a HEMT may also be referred to as heterostructure FET (HFET). A HEMT may also be referred to as a modulation-doped FET (MODFET). This contrasts with the doped region that is typically used as a channel in metal-oxide semiconductor FETs (MOSFETs). HEMTs are typically characterized by relatively low on-state resistance, high breakdown voltage, and low switching losses.

Typical HEMTs are used in power amplifiers, wireless communication systems, voltage converters, and other applications.

In operation, a HEMT generates an electromagnetic field. In some cases, the electromagnetic field may interfere with the operation of the gate. Some HEMTs include a metal structure for alleviating effects of the electromagnetic field, which may be referred to as a field plate.

### BRIEF DESCRIPTION OF THE DRAWINGS

A more detailed understanding can be had from the following description, given by way of example in conjunction with the accompanying drawings wherein:

FIG. 1 is a cross-sectional view of an example HEMT;

FIG. 2 is a cross-sectional view of the example HEMT of FIG. 1, illustrating electric field distributions;

FIG. 3A is a cross-sectional view of another example HEMT;

FIG. 3B is an enlarged view of a portion of FIG. 3A, showing detail of the example HEMT of FIG. 3A.

FIG. 4 is a cross-sectional view of the example HEMT of FIGS. 3A and 3B, illustrating electric field distributions;

FIG. 5 is a line graph illustrating field strength at an AlGaN region of the HEMT of FIGS. 1 and 2, corresponding to the electric fields illustrated in FIG. 2;

FIG. 6 is a line graph illustrating field strength at an AlGaN region of the HEMT of FIGS. 3A, 3B, and 4, corresponding to the electric fields illustrated in FIG. 4;

FIG. 7 is a line graph illustrating field strength at a two dimensional electron gas (2DEG) region of the HEMT of FIGS. 1 and 2, corresponding to the electric fields illustrated in FIG. 2;

FIG. 8 is a line graph illustrating field strength at a 2DEG region of the HEMT of FIGS. 3A, 3B, and 4, corresponding to the electric fields illustrated in FIG. 4;

FIG. 9 is a plan view of the HEMT of FIGS. 3A, 3B, and 4; and

FIG. 10 is a flow chart illustrating example steps for manufacturing an example HEMT.

### SUMMARY

A high electron mobility transistor (HEMT) which includes a source disposed on a surface, a drain disposed on the surface, a gate disposed on the surface between the source and the drain, and a first field plate disposed on the surface between the gate and the drain. In some implementations, the first field plate includes a p-type doped GaN (P-GaN). In some implementations, the first field plate includes a doping concentration, doping material, geometry, and/or position that is configured to minimize an increase of an on-resistance of the HEMT. In some implementations, the first field plate extends continuously between and parallel to the source and the drain regions, such that any path from the source to the drain passes under, through, or over the first field plate. In some implementations, the first field plate extends continuously beyond an entire width of the surface between the source and the drain.

### DETAILED DESCRIPTION

Some implementations provide a high electron mobility transistor (HEMT). The HEMT includes a source disposed on a surface, a drain disposed on the surface, a gate disposed on the surface between the source and the drain, and a first field plate disposed on the surface between the gate and the drain.

In some implementations, the first field plate includes doped gallium nitride (GaN). In some implementations, the first field plate is at a floating voltage. In some implementations, the first field plate is not electrically connected to a voltage source. In some implementations, a second field plate is disposed on the surface between the gate and the first field plate. In some implementations, the second field plate is electrically connected to a voltage source. In some implementations, the second field plate is electrically connected to the source. In some implementations, the first field plate includes GaN and has a different concentration of dopant, a different type of dopant, or a different dopant material, than the gate. In some implementations, the first field plate includes a doping concentration, doping material, geometry, and/or position that is configured to minimize an increase of an on-resistance of the HEMT. In some implementations, the first field plate is continuous. In some implementations, the first field plate extends continuously between and parallel to the source and the drain regions, such that any path from the source to the drain passes under, through, or over the first field plate. In some implementations, the first field plate extends continuously beyond an entire width of the surface between the source and the drain. In some implementations, the first field plate is closer to the gate than to the drain. In some implementations, the first field plate includes a p-type doped GaN (P-GAN). In some implementations, the first field plate includes a p-type doped aluminum gallium nitride GaN (AlGaN) or an n-type doped AlGaN.

Some implementations provide a method for manufacturing a high electron mobility transistor (HEMT). A gate material is deposited on a surface between a source and a drain. A first field plate material is deposited on the surface between the gate material and the drain.

In some implementations, the gate material and the first field plate material include doped gallium nitride (GaN). In some implementations, the first field plate material extends continuously across the surface between the source and the drain, such that any path from the source to the drain passes under, through, or over the first field plate material. In some implementations, the first field plate material includes a p-type doped GaN (P-GaN). In some implementations, the first field plate material includes a p-type doped aluminum gallium nitride (AlGaN) or an n-type doped AlGaN.

Reference will now be made in detail to various embodiments, examples of which are illustrated in the accompanying drawings. While the description is made in conjunction with these embodiments, it is understood that they are not intended to limit the claims to these embodiments. On the contrary, the description is intended to cover alternatives, modifications and equivalents, which may be included within the spirit and scope of the description as defined by the appended claims. Furthermore, in the following detailed description of the invention, numerous specific details are set forth to provide a thorough understanding. However, it will be recognized by one of ordinary skill in the art that various embodiments may be practiced without these specific details. In other instances, well known methods, procedures, components, and circuits have not been described in detail as not to unnecessarily obscure aspects of the embodiments.

Certain terminology is used in the following description for convenience only and is not limiting. The words “right,” “left,” “top,” and “bottom” designate directions in the drawings to which reference is made. The words “a” and “one,” as used in the claims and in the corresponding portions of the specification, are defined as including one or more of the referenced item unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof. It may be noted that some figures are shown with partial transparency for the purpose of explanation, illustration and demonstration purposes only, and is not intended to indicate that an element itself would be transparent in its final manufactured form.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present description. As used herein, the term “and/or” includes any and all combinations of one or more of the associated listed items.

It will be understood that when an element such as a layer, region, substrate, lead, clip, pad, or contact is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will be understood that these terms are intended to encompass different orientations of the element in addition to any orientation depicted in the figures.

Relative terms such as “below” or “above” or “upper” or “lower” or “horizontal” or “vertical” may be used herein to describe a relationship of one element, layer or region to another element, layer, region. It will be understood that these terms are intended to encompass different orientations of the device in addition to the orientation depicted in the figures.

The figures are not drawn to scale, and only portions of the structures, as well as the various layers that form those structures, may be shown in the figures. The figures, in general, illustrate symbolic and simplified structures for understanding, and are not intended to reproduce physical structures in detail. Furthermore, fabrication processes and operations may be performed along with the processes and operations discussed herein; that is, there may be a number of process operations before, in between and/or after the operations shown and described herein. Further, embodiments can be implemented in conjunction with these other (perhaps conventional) processes and operations without significantly perturbing them. Generally, embodiments may replace and/or supplement portions of a conventional process without significantly affecting peripheral processes and operations.

The term “HEMT” is generally understood to be synonymous with the terms heterostructure FET (HFET) and modulation-doped FET (MODFET). The term “HEMT” includes devices commonly known as or referred to as HEMTs, HFETs, or MODFETs.

The term “MOSFET” is generally understood to be synonymous with the term insulated-gate field-effect transistor (IGFET), as many modern MOSFETs comprise a non-metal gate and/or a non-oxide gate insulator. As used herein, the term “MOSFET” does not necessarily imply or require FETs that include metal gates and/or oxide gate insulators. Rather, the term “MOSFET” includes devices commonly known as or referred to as MOSFETs.

The term “substantially” in the description and claims of the present application is used to refer to design intent, rather than a physical result. The semiconductor arts have deployed an ability to measure numerous aspects of a semiconductor to a high degree of accuracy. Accordingly, when measured to available precision, in general, no physical aspect of a semiconductor is precisely as designed. Further, measurement technology may readily identify differences in structures that are intended to be identical. Accordingly, terms such as “substantially equal” should be interpreted as designed to be equal, subject to manufacturing variation and measurement precision.

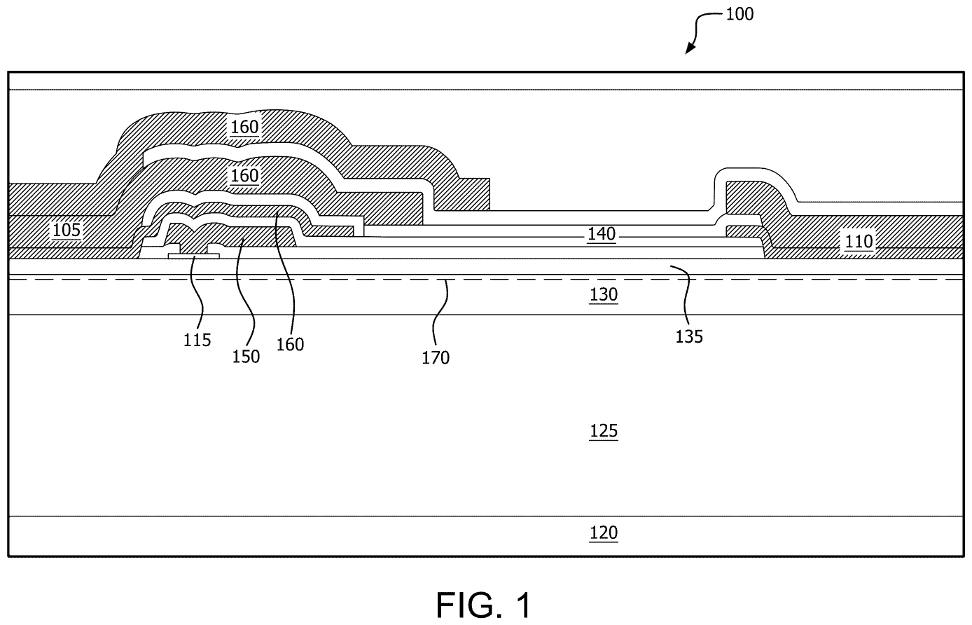

FIG. 1 is a cross-sectional view of an example HEMT 100. HEMT 100 includes a source contact 105, drain contact 110, gate 115, substrate 120, buffer layer 125, channel layer 130, barrier layer 135, dielectric 140, gate contact 150, and field plates 160. HEMT 100 is an enhancement mode device for purposes of example, however it is noted that the principles described herein also apply to depletion mode HEMT devices. Some implementations include a subset of the example components described with respect to FIG. 1, or additional components. For example, some implementations include a source, gate, and drain on a substrate which includes a different combination of layers, or omits field plates.

In the example of FIG. 1, HEMT 100 is in an off state when gate contact 150 and source contact 105 are both at ground potential, and is in an on state when gate contact 150 is above a threshold voltage. Barrier layer 135 has a higher bandgap than the channel layer 130 thus facilitating the formation of 2DEG 170. In the on state, as drain contact 110 increases in potential relative to source contact 105, electric fields force high-mobility electrons in 2DEG 170 toward drain contact 110 from source contact 105, allowing current to flow. The existence of 2DEG 170 below gate contact 150 depends on the voltage applied to gate contact 150. Above a threshold gate voltage, 2DEG 170 is continuous between source contact 105 and drain contact 110. Below the threshold gate voltage, 2DEG 170 becomes depleted until there is a break in 2DEG 170 below gate contact 150 between source contact 105 and drain contact 110. As gate contact 150 is brought below the threshold gate voltage, 2DEG 170 is blocked from flowing between drain contact 110 and source contact 105, preventing current flow and causing HEMT 100 to enter the off state.

Substrate 120 may be made from any suitable material, such as silicon (Si), an engineered substrate (e.g., QST®), silicon carbide (SiC), gallium nitride (GaN) or any other suitable material or combinations of materials, e.g., such as materials capable of supporting growth of a Group-III nitride material. In this example, substrate 120 is made from QST. In some implementations, a nucleation layer (not shown) may be formed on the substrate 120, e.g., to reduce lattice mismatch between the substrate and buffer layer 125 of the HEMT 100. The nucleation layer may include any suitable material, and may be formed on substrate 120 using any suitable semiconductor growth technique or techniques, such as metal oxide chemical vapor deposition (MOCVD), hybrid vapor phase epitaxy (HVPE), or molecular beam epitaxy (MBE).

Buffer layer 125 may be formed on substrate 120 (or the corresponding nucleation layer). In some implementations, buffer layer 125 is or includes a high resistivity material. In this context, a high resistivity material is a material having a resistivity that does not cause leakage current above a desired amount (e.g., above a threshold leakage current) in the device. In some implementations, such material may have a doping concentration of (or approximately of, or on the order of) 1×10¹⁵/cm³ (either intentionally or unintentionally doped). In some implementations, buffer layer 125 includes doped or undoped layers of Group-III nitride materials. In this example, buffer layer 125 is made from single-or multi-layer AlGaN, however any suitable Group-III nitride materials may be used. In some implementations, buffer layer 125 is doped with iron, carbon, or any other suitable dopant, e.g., to reduce trap density. Buffer layer 125 may be formed on substrate 120 (or the corresponding nucleation layer) using AlN or any suitable semiconductor growth technique or techniques, such as metal oxide chemical vapor deposition (MOCVD), hybrid vapor phase epitaxy (HVPE), or molecular beam epitaxy (MBE).

Channel layer 130 may be formed on buffer layer 125. In some implementations, channel layer 130 includes any suitable doped or undoped Group III-nitride materials. In this example, channel layer is made from GaN, however any suitable Group-III nitride materials may be used. Channel layer 130 may be formed on buffer layer 125 using any suitable semiconductor growth technique or techniques, such as MOCVD, HVPE, or MBE.

In some implementations, channel layer 130 has a thickness suitable to prevent wafer bow. In some implementations, channel layer 130 has a minimum thickness suitable to prevent wafer bow. In some implementations, channel layer 130 has a thickness in the range of few hundred nanometers. In some implementations, channel layer 130 is a high resistance layer which may be made of an unintentionally doped or low doped material. In this context, a high resistance material is a material having a resistance that does not cause leakage current above a desired amount (e.g., above a threshold leakage current) in the device. In some implementations, such material may have a doping concentration of (or approximately of, or on the order of) 1×10¹⁵/cm3 (either intentionally or unintentionally doped). In some implementations, channel layer 130 is or includes an n-type Group-III nitride material. Conceptually, some implementations may use a p-type Group-III nitride material, where the device is configured to operate using a two-dimensional hole gas (2DHG).

Barrier layer 135 may be formed on channel layer 130. Like buffer layer 125, barrier layer 135 may include doped or undoped layers of Group-III nitride materials. Barrier layer 135 may be formed on channel layer 130 using any suitable semiconductor growth technique or techniques, such as MOCVD, HVPE, or MBE. In some this example, barrier layer 135 comprises AlGaN with a thickness in the range of 12-25 nm for an Al mole fraction of 0.18 to 0.23. In some implementations, thickness of barrier layer 135 may vary among different regions of the device (e.g., barrier layer 135 may have different thicknesses below the gate 115 and/or in the drain access region and/or below source contact 105 and/or drain contact 110.).

Gate 115 may be formed on a surface of barrier layer 135. In some implementations, Gate 115 includes any suitable Group-III nitride material. In this example, gate 115 is made of doped GaN (p-type GaN in this example) grown on barrier layer 135. In some implementations, gate 115 has a non-uniform doping concentration (p-type in this example). For example, such non-uniform doping concentration may be selected to form a specific electric field and depletion region within gate 115.

Gate 115 may be formed on the surface of barrier layer 135 using any suitable semiconductor growth technique or techniques, such as MOCVD, HVPE, or MBE. In some implementations, gate 115 is made from GaN (e.g., p-type GaN). In some implementations, gate 115 has a doping concentration in the range of 1×10¹⁶-1×10²⁰ cm³ (e.g., 2-3×10¹⁹ cm³) and a thickness in the range of 50-150 nm.

Gate contact 150 is an electrode in Schottky or Ohmic contact with gate 115 and formed using any suitable metal deposition technique or techniques. Gate contact 150 is made from aluminum or any other suitable metal, stacks of metals, or any other conductor or conductor layers. In some implementations, these materials are configured to provide an Ohmic or Schottky contact. In some implementations, gate contact 150 extends over, but not contacting (e.g., separated by a dielectric), barrier layer 135 in the direction of drain contact 110 as shown in FIG. 1. In some such implementations, the extending portion of gate contact 150 may function as a field plate to shield gate 115 from electric fields (e.g., high electric fields, such as fields having a strength above a threshold field strength, or electric fields higher than the critical electric fields (E_{c}) of materials of one or more layers. In some implementations, E_{c} is typically equal to or on the order of 4 MV/cm).

Drain contact 110 is an electrode exhibiting Ohmic characteristics at a barrier interface with barrier layer 135, forming a drain region. Drain contact 110 includes one or more metal layers disposed on barrier layer 135 to form a drain region of HEMT 100. Drain contact 110 is made from aluminum or any other a suitable metal, metal stack, or other conductor. Drain contact 110 includes one or more contacting metal layers disposed on barrier layer 135.

Source contact 105 is an electrode exhibiting Ohmic characteristics at a barrier interface with barrier layer 135, forming a source region. Source contact 105 is made from aluminum or any other suitable metal, metal stack, or other conductor. Source contact 105 includes one or more contacting metal layers disposed on barrier layer 135. In some implementations, source contact 105 extends over barrier layer 135 in the direction of drain contact 110, without contacting barrier layer 135, as shown in FIG. 1. In some such implementations, the extending portion of gate contact 150 may function as a field plate to shield gate 115 from electric fields (e.g., high electric fields, such as fields having a strength above a threshold field strength, or higher than E_{c} of materials of one or more layers. In some implementations, E_{c} is typically equal to or on the order of 4 MV/cm.). In some implementations, several layers of metal are deposited to form source contact 105, and portions of each of the metal layers extend over barrier layer 135 in the direction of drain contact 110, without contacting barrier layer 135, as shown in FIG. 1. In some such implementations, the multiple extending portions of source contact 105 may function as a field plates to shield gate 115 from electric fields (e.g., high electric fields, such as fields having a strength above a threshold field strength, or higher than E_{c} of materials of one or more layers. In some implementations, E_{c} is typically equal to or on the order of 4 MV/cm). In some such implementations, dielectric 140 is deposited between the extending portions of each metal layer of source contact 105 that form the field plates, between the field plates and gate contact 115, and between the field plates and barrier layer 135, e.g., as shown in FIG. 1.

Dielectric 140 is a dielectric material, such as silicon nitride (SiN), silicon dioxide (SiO2), aluminum oxide (Al203), any other suitable dielectric material, or any suitable combination of these or other dielectric materials. Dielectric 140 is deposited over HEMT 100 as shown in FIG. 1 to electrically and physically isolate structures of HEMT 100 from the environment and from each other. In some implementations, dielectric 140 is deposited in several layers. For example, as shown in FIG. 1, dielectric 140 is deposited in a first layer over barrier layer 135 and gate 115. In this example, the first layer of dielectric 140 is patterned and etched or otherwise treated to expose gate 115 so that gate contact 150 can be deposited on gate 115. After gate contact 150 is deposited, a second layer of dielectric 140 is deposited to cover gate contact 150 and the first layer of dielectric 140. The layers of dielectric 140 are patterned and etched or otherwise treated to so that a first layer of source contact 105 can be deposited on barrier layer 135, and a portion of the source contact 105 can be deposited on the second layer of dielectric 140 to form field plate 160. Patterning, etching, and depositing of a plurality of layers of dielectric 140 may be performed repeatedly to yield the layers of dielectric 140 and other structures of HEMT as shown in FIG. 1, or any other suitable HEMT structures.

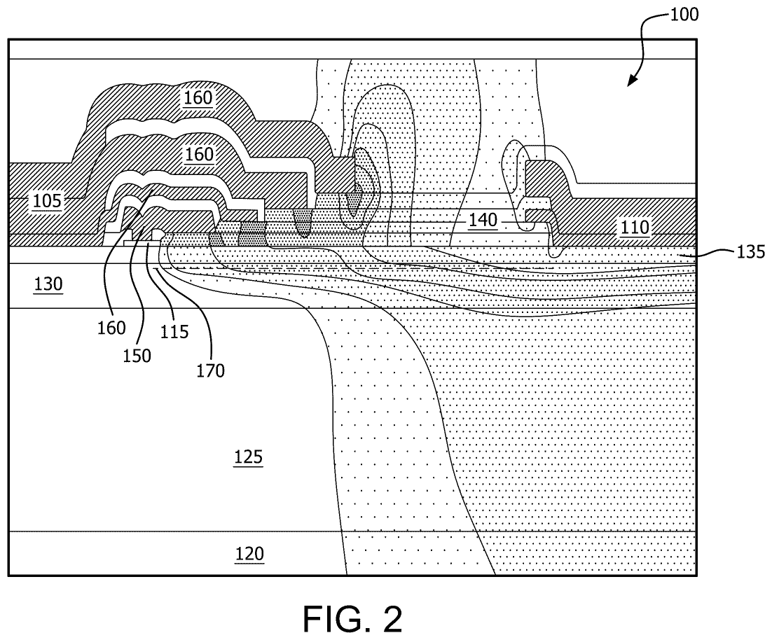

FIG. 2 is a cross-sectional view of the example HEMT 100 shown and described with respect to FIG. 1, further illustrating electric fields that are present when HEMT 100 is in an off state. In this example, HEMT 100 is an enhancement mode device. Accordingly, in the off state, gate contact 150 and source contact 105 are both at ground potential, while drain contact 110 is at a relatively higher potential.

In this example, in the off state, the ground potential of gate 115 prevents 2DEG 170 from flowing from source contact 105 to drain contact 110 through channel layer 130. As illustrated by the shading overlaying HEMT 100 in FIG. 2, in the off state with a positive voltage at drain contact 110, the electric field is strong in an area immediately adjacent to gate 115 (i.e., at the edge of gate 115). It is noted that this is true even though field plates 160 moderate the electric field to some degree. In some cases, the strong electric field present at the edge of gate 115 may cause or contribute to unsuitable operating characteristics of HEMT 100, and/or promote electron or hole trapping which may lead to gate and device failure. For example, in some cases such electric fields may have the effect of degrading the device threshold voltage of HEMT 100, creating drain-source leakage and/or gate-source-drain leakage in HEMT 100, and/or promoting gate failure during aging or burn-in of HEMT 100.

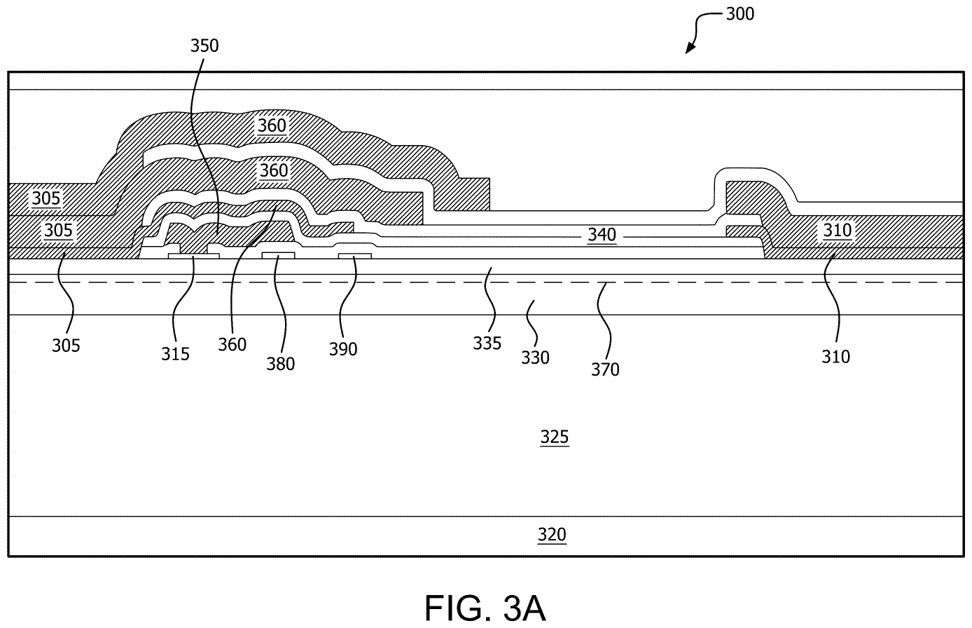

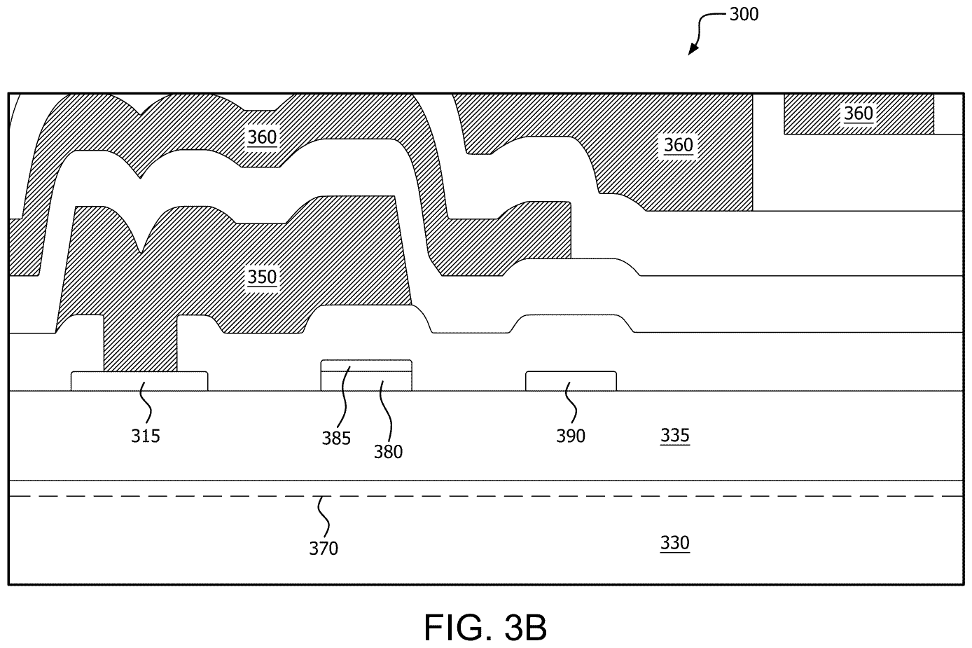

FIG. 3A is a cross-sectional view of an example HEMT 300. HEMT 300 includes a source contact 305, drain contact 310, gate 315, substrate 320, buffer layer 325, channel layer 330, barrier layer 335, dielectric 340, gate contact 350, and field plates 360. HEMT 300 also includes a field plate 380 and field plate 390.

HEMT 300 is substantially similar in structure and materials to HEMT 100 as shown and described with respect to FIGS. 1 and 2, except that it includes two field plates, field plate 380 and field plate 390, on the surface of barrier layer 335, and structural accommodation for field plate 380 and field plate 390. HEMT 300 includes two such field plates, however it is noted that in other implementations, a HEMT may include only one such field plate, or more than two such field plates.

HEMT 300 is an enhancement mode device for purposes of example, however it is noted that the principles described herein also apply to depletion mode HEMT devices. Some implementations include a subset of the example components described with respect to FIG. 3A, or additional components. For example, some implementations include a source, gate, and drain on a substrate which includes a different combination of layers, or omits field plates.

In the example of FIG. 3A, HEMT 300 is in an off state when gate contact 350 and source contact 305 are both at ground potential, and is in an on state when gate contact 350 is above a threshold voltage. Barrier layer 335 has a higher bandgap than the channel layer 330 thus facilitating the formation of 2DEG 370. In the on state, as drain contact 310 increases in potential relative to source contact 305, electric fields force high-mobility electrons in 2DEG 370 toward drain contact 310 from source contact 305, allowing current to flow. The existence of 2DEG 370 below gate contact 350 depends on the voltage applied to gate contact 350. Above a threshold gate voltage, 2DEG 370 is continuous between source contact 305 and drain contact 310. Below the threshold gate voltage, 2DEG 370 becomes depleted until there is a break in 2DEG 370 below gate contact 350 between source contact 305 and drain contact 310. As gate contact 150 is brought below the threshold gate voltage, 2DEG 370 is blocked from flowing between drain contact 310 and source contact 305, preventing current flow and causing HEMT 300 to enter the off state.

Substrate 320 may be made from any suitable material, such as silicon (Si), an engineered substrate (e.g., QST®), silicon carbide (SiC), gallium nitride (GaN) or any other suitable material or combinations of materials, e.g., such as materials capable of supporting growth of a Group-Ill nitride material. In this example, substrate 320 is made from QST. In some implementations, a nucleation layer (not shown) may be formed on the substrate 320, e.g., to reduce lattice mismatch between the substrate and buffer layer 325 of the HEMT 300. The nucleation layer may include any suitable material, and may be formed on substrate 320 using any suitable semiconductor growth technique or techniques, such as metal oxide chemical vapor deposition (MOCVD), hybrid vapor phase epitaxy (HVPE), or molecular beam epitaxy (MBE).

Buffer layer 325 may be formed on substrate 320 (or the corresponding nucleation layer). In some implementations, buffer layer 325 is or includes a high resistivity material. In this context, a high resistivity material is a material having a resistivity that does not cause leakage current above a desired amount (e.g., above a threshold leakage current) in the device. In some implementations, such material may have a doping concentration of (or approximately of, or on the order of) 1×10¹⁵/cm3 (either intentionally or unintentionally doped). In some implementations, buffer layer 325 includes doped or undoped layers of Group-III nitride materials. In this example, buffer layer 325 is made from single-or multi-layer AlGaN, however any suitable Group-III nitride materials may be used. Buffer layer 325 may be formed on substrate 320 (or the corresponding nucleation layer) using any suitable semiconductor growth technique or techniques, such as MOCVD, HVPE, or MBE.

Channel layer 330 may be formed on buffer layer 325. In some implementations, channel layer 330 includes any suitable doped or undoped Group III-nitride materials. In this example, channel layer is made from GaN, however any suitable Group-III nitride materials may be used. Channel layer 330 may be formed on buffer layer 325 using any suitable semiconductor growth technique or techniques, such as MOCVD, HVPE, or MBE.

Field plate 380 may be formed on a surface of barrier layer 335 using any suitable semiconductor growth technique or techniques, such as MOCVD, HVPE, or MBE. In some implementations, field plate 380 is made from GaN (e.g., p-type GaN). In some implementations, field plate 380 functions as a field plate to shield gate 315 from electric fields (e.g., high electric fields, such as fields having a strength above a threshold field strength).

In some implementations, field plate 380 is formed from a same layer of GaN (e.g., P-GAN) material (e.g., by patterning and/or etching) used to form gate 315.

In some implementations, field plate 380 has a doping concentration that is different from a doping concentration of gate 315. In some implementations, field plate 380 is doped with a dopant material that is different from a dopant material of gate 315. In some implementations, field plate 380 has a doping concentration in the range of 1×10¹⁶-1×10²⁰ cm³ (e.g., 2-3×10¹⁹ cm³). In some implementations, field plate 380 is substantially thinner than gate 315. In some implementations, field plate 380 has a thickness of or of approximately one-third to one-half that of gate 335. In some implementations, field plate 380 has dimensions (e.g., length, height, width) that differ from those of gate 335. In some implementations, the reduced thickness or different dimensions of field plate 380 as compared with gate 315 is achieved by applying a mask and etch process to field plate 380. In some implementations, field plate 380 is electrically connected to or in communication with source contact 305 via metal, or otherwise held at the same potential as source contact 305. In some implementations, field plate 380 is formed from a different material than the material used to form gate 315. For example, in a case where gate 315 is formed from PGaN, field plate 380 may be formed from AlGaN.

Field plate 390 may be formed on a surface of barrier layer 335. In some implementations, field plate 390 includes any suitable Group-III nitride material. In this example, field plate 390 is made of doped GaN (P-type GaN in this example) grown on barrier layer 335. In some implementations, field plate 390 has a non-uniform doping concentration (p-type in this example). For example, in some implementations, such non-uniform doping concentration may be selected to form a specific electric field and depletion region within field plate 390.

Field plate 390 may be formed on a surface of barrier layer 335 using any suitable semiconductor growth technique or techniques, such as MOCVD, HVPE, or MBE. In some implementations, field plate 390 is made from GaN (e.g., p-type GaN). In some implementations, field plate 380 functions as a field plate to shield gate 315 from electric fields (e.g., high electric fields, such as fields having a strength above a threshold field strength).

In some implementations, field plate 390 is formed from a same layer of GaN (e.g., P-GaN) material (e.g., by patterning and/or etching) used to form gate 315 and/or field plate 380. In some implementations, field plate 390 has a doping concentration that is different from a doping concentration of gate 315. In some implementations, field plate 390 is doped with a dopant material that is different from a dopant material of gate 315. In some implementations, field plate 390 has a doping concentration in the range of 1×10¹⁶-1×10²⁰ cm³ (e.g., 2-3×10¹⁹ cm³). In some implementations, field plate 390 is substantially thinner than gate 315. In some implementations, field plate 390 has a thickness of or of approximately one-third to one-half that of gate 335. In some implementations, field plate 390 has dimensions (e.g., length, height, width) that differ from those of gate 335. In some implementations, the reduced thickness or different dimensions of field plate 390 as compared with gate 315 is achieved by applying a mask and etch process to field plate 390 (e.g., a same process used to achieve the thickness of field plate 380).

In some implementations, field plate 390 floats and is not electrically connected with or in communication with source contact 105 via metal, or otherwise held at the same potential as source contact 105. It is noted that field plate 390 is closer to drain 110 than field plate 380. In some implementations with more than one such field plate, the field plate closest to the drain floats and is not electrically connected to or in communication with ground via metal. In some implementations with only one such field plate, the single field plate floats and is not electrically connected to or in communication with ground via metal.

Gate contact 350 is an electrode in Schottky or Ohmic contact with gate 315 and formed using any suitable metal deposition technique or techniques. Gate contact 350 is made from aluminum or any other a suitable metal, stacks of metals, or any other conductor or conductor layers. In some implementations, these materials are configured to provide an Ohmic or Schottky contact. In some implementations, gate contact 350 extends over, but not contacting (e.g., separated by a dielectric), barrier layer 335 in the direction of drain contact 310 as shown in FIG. 3A. In some such implementations, the extending portion of gate contact 350 may function as a field plate to shield gate 315 from electric fields (e.g., high electric fields, such as fields having a strength above a threshold field strength).

Drain contact 310 is an electrode exhibiting Ohmic characteristics at a barrier interface with barrier layer 335, forming a drain region. Drain contact 310 includes one or more metal layers disposed on barrier layer 335 to form a drain region of HEMT 300. Drain contact 310 is made from aluminum or any other a suitable metal or other conductor. Drain contact 310 includes one or more contacting metal layers disposed on barrier layer 335.

Source contact 305 is an electrode exhibiting Ohmic characteristics at a barrier interface with barrier layer 335, forming a source region. Source contact 305 is made from aluminum or any other suitable metal or other conductor. Source contact 305 includes one or more contacting metal layers disposed on barrier layer 335. In some implementations, source contact 305 extends over barrier layer 335 in the direction of drain contact 310, without contacting barrier layer 335, as shown in FIG. 3A. In some such implementations, the extending portion of gate contact 350 may function as a field plate to shield gate 315 from electric fields (e.g., high electric fields, such as fields having a strength above a threshold field strength).

In some implementations, several layers of metal are deposited to form source contact 305, and portions of each of the metal layers extend over barrier layer 335 in the direction of drain contact 310, without contacting barrier layer 335, as shown in FIG. 3A. In some such implementations, the multiple extending portions of source contact 305 may function as a field plates to shield gate 315 from electric fields (e.g., high electric fields, such as fields having a strength above a threshold field strength). In some such implementations, dielectric 340 is deposited between the extending portions of each metal layer of source contact 305 that form the field plates, between the field plates and gate contact 315, and between the field plates and barrier layer 335, e.g., as shown in FIG. 3A.

It is noted that in some implementations, field plates 380 and 390 have the advantage of providing significantly more shielding of gate 315 from electric fields (e.g., are more effective in controlling the peak electric field at the edge of gate 315) than the field plates formed by field plates 360, e.g., due to their proximity to gate 315. Accordingly, in some implementations, field plates 360 are omitted. Omitting field plates 360 may have the advantage of reducing parasitic capacitances between the metal of the source contact 305 and drain contact 310.

Dielectric 340 is a dielectric material, such as silicon nitride (SiN), silicon dioxide (SiO2), aluminum oxide (Al203), or any other suitable dielectric material. Dielectric 340 is deposited over HEMT 300 as shown in FIG. 3A to electrically and physically isolate structures of HEMT 300 from the environment and from each other. In some implementations, dielectric 340 is deposited in several layers. For example, as shown in FIG. 3A, dielectric 340 is deposited in a first layer over barrier layer 335 and gate 315. In this example, the first layer of dielectric 340 is patterned and etched or otherwise treated to expose gate 315 so that gate contact 350 can be deposited on gate 315. After gate contact 350 is deposited, a second layer of dielectric 340 is deposited to cover gate contact 350 and the first layer of dielectric 340. The layers of dielectric 340 are patterned and etched or otherwise treated to so that a first layer of source contact 305 can be deposited on barrier layer 335, and a portion of the source contact 305 can be deposited on the second layer of dielectric 340 to form field plate 360. Patterning, etching, and depositing of a plurality of layers of dielectric 340 may be performed repeatedly to yield the layers of dielectric 340 and other structures of HEMT as shown in FIG. 3A, or any other suitable HEMT structures.

FIG. 3B is an enlarged view of HEMT 300, showing additional structure. As shown in FIG. 3B, a metal contact 385 is deposited on field plate 380. Metal contact 385 creates an electrical connection between field plate 380 and source contact 305 via a metal layer or layers (connecting portion of metal contact 385 not shown).

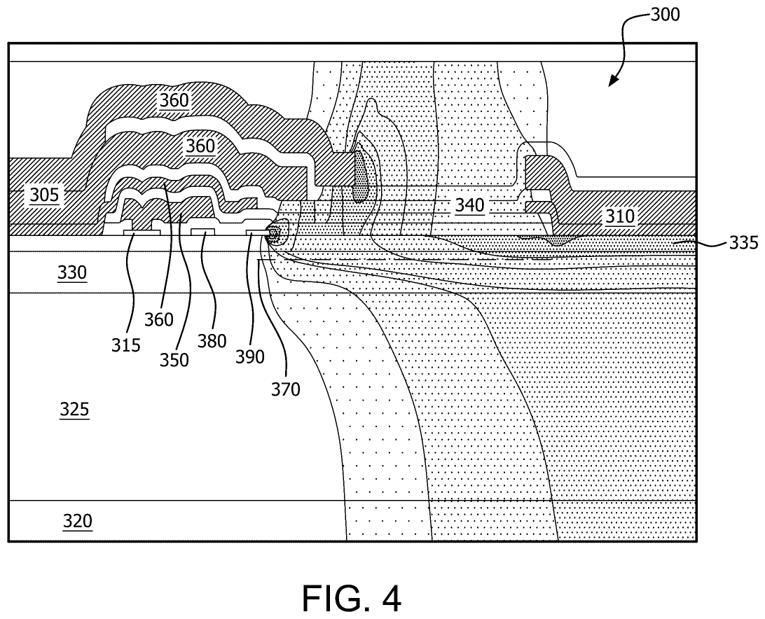

FIG. 4 is a cross-sectional view of the example HEMT of FIG. 3, further illustrating electric fields that are present when HEMT 300 is in an off state. In this example, HEMT 300 is an enhancement mode device. Accordingly, in the off state, gate contact 350 and source contact 305 are both at ground potential, while drain contact 310 is at a relatively higher potential.

In this example, in the off state, the ground potential of gate 315 prevents 2DEG 370 from flowing from drain contact 310 to source contact 305 through channel layer 330. As illustrated by the shading overlaying HEMT 300 in FIG. 4 in the off state with a positive voltage at drain contact 310, the electric field is strong in an area immediately adjacent to field plate 390, but is substantially absent from the area of the gate 315. In some cases, this is due to the shielding effect of field plate 390 and/or 380. In some cases, this has the advantage of preventing or reducing unsuitable operating characteristics of HEMT 300, and/or electron or hole trapping that may otherwise be caused or contributed to by a strong electric field present at the edge of gate 315. For example, in some cases this has the advantage of avoiding degradation of the device threshold voltage of HEMT 300, avoiding drain-source leakage and/or gate-source-drain leakage in HEMT 300, avoiding gate damage during aging or burn-in of HEMT 300, and/or avoiding electron or hole trapping which may lead to gate and device failure.

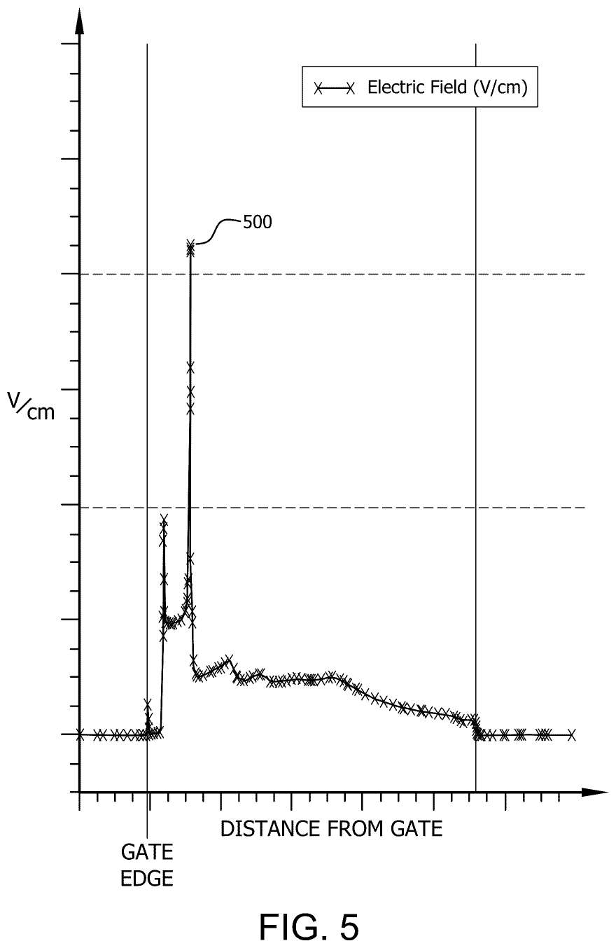

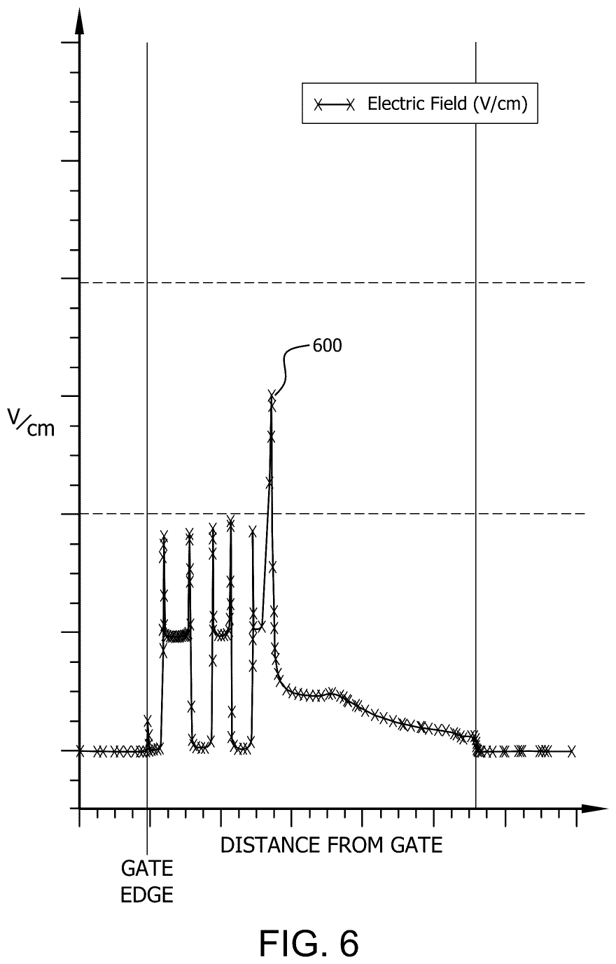

FIG. 5 is a line graph illustrating electric field strength in HEMT 100 at the border of barrier layer 135 and dielectric 140 due to the electric fields illustrated in FIG. 2. The electric field strength is plotted against distance from the edge of gate 115 in the direction of drain 110. A peak field strength 500 is indicated. FIG. 6 is a line graph illustrating electric field strength in HEMT 300 at the border of barrier layer 335 and dielectric 340 due to the electric fields illustrated in FIG. 4. The electric field strength is plotted against distance from the edge of gate 315 in the direction of drain 310. A peak field strength 600 is indicated.

It is noted that the distance between gate 315 and the electric field at peak field strength 600 is further than the distance between gate 115 and the electric field at peak field strength 500. Peak field strength 600 is also lower than the peak field strength 500. In some implementations, this difference is due to the shielding effects of field plate 390 and/or 380. In some implementations, the increased distance from gate 315 to peak field strength 600 has the advantage of preventing or reducing unsuitable operating characteristics of HEMT 300 that may otherwise be caused or contributed to by a strong electric field present at the edge of gate 315.

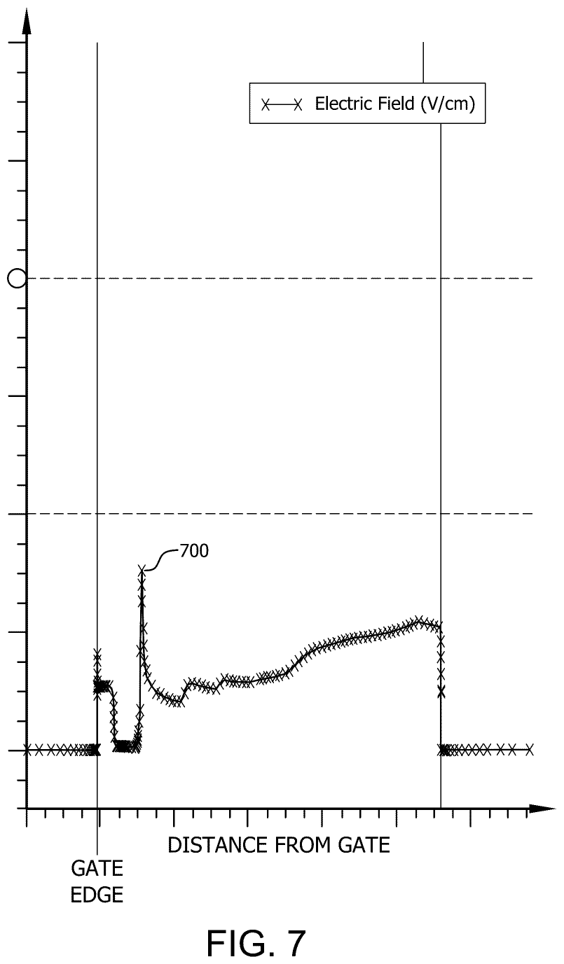

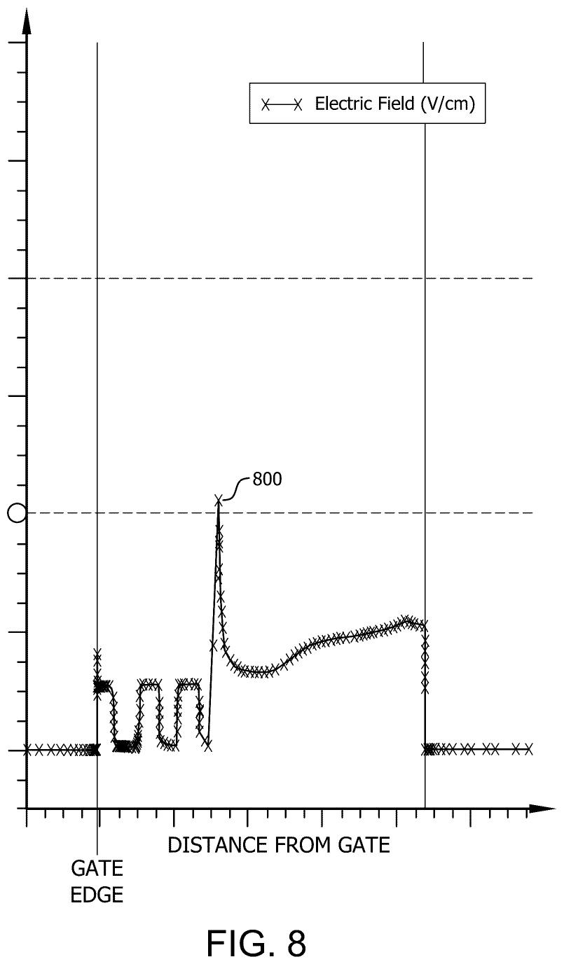

FIG. 7 is a line graph illustrating electric field strength in HEMT 100 at 2DEG 170 due to the electric fields illustrated in FIG. 2. The electric field strength is plotted against distance from the edge of gate 115 in the direction of drain 110. A peak field strength 700 is indicated. FIG. 8 is a line graph illustrating electric field strength in HEMT 300 at 2DEG 170 due to the electric fields illustrated in FIG. 4. The electric field strength is plotted against distance from the edge of gate 315 in the direction of drain 310. A peak field strength 800 is indicated.

It is noted that the distance between gate 315 and the electric field at peak field strength 800 is further than the distance between gate 115 and the electric field at peak field strength 700. In some implementations, this difference is due to the shielding effects of field plate 390 and/or 380. In some implementations, the increased distance from gate 315 to peak field strength 800 has the advantage of preventing or reducing unsuitable operating characteristics of HEMT 300 that may otherwise be caused or contributed to by a strong electric field present at the edge of gate 315. It is noted that in some implementations this is true even though peak field strength 800 is higher than the peak field strength 700, e.g., due to the increased distance from gate 315.

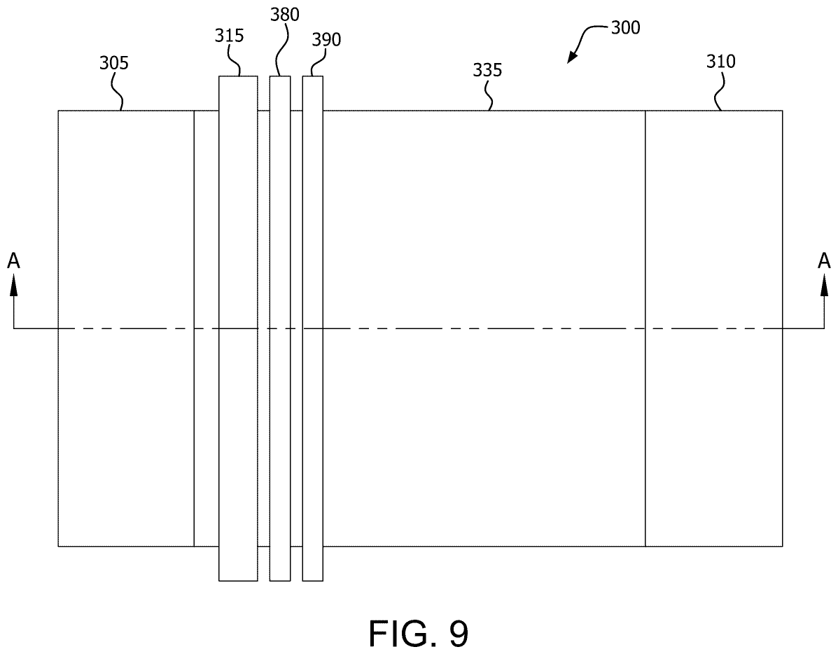

FIG. 9 is a plan view of HEMT 300 as shown and described with respect to FIGS. 3A, 3B and 4. Cross-section A indicates the view as shown in FIGS. 3A, 3B and 4. Several features of HEMT 300 are omitted from FIG. 9 for clarity. As shown in FIG. 9, field plate 380 and field plate 390 extend continuously and entirely across (in the vertical direction as shown in FIG. 9) HEMT 300 such that any path along (in the horizontal direction as shown in FIG. 9) HEMT 300 between source 305 and drain 310 passes under, through, or over field plate 380 and field plate 390. In some implementations, the continuity of field plates 380 and 390 has the advantage of preventing or reducing the effects of strong electric fields on gate 315 when HEMT 300 is in the off state and a voltage at drain 310 is increasing.

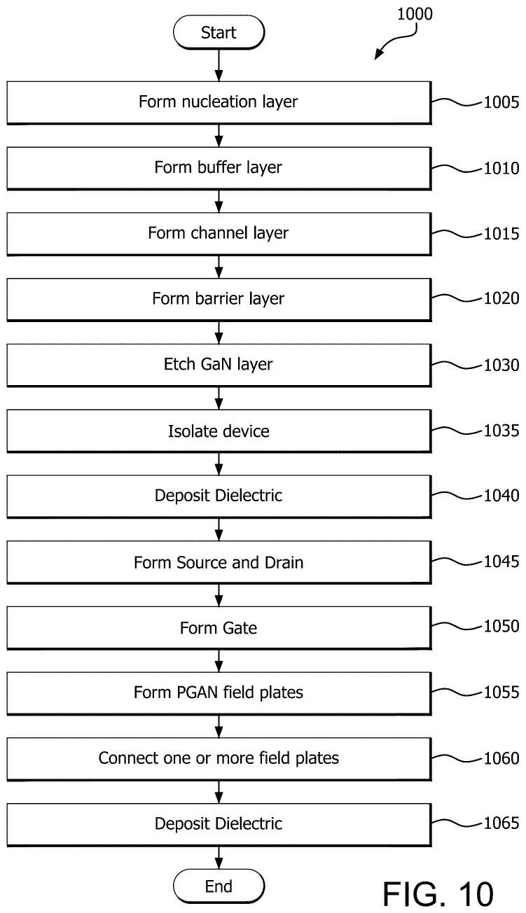

FIG. 10 is a flow chart illustrating example steps process 1000 for manufacturing an example HEMT. For example, HEMT 300 as shown and described above may be manufactured using some or all of the steps of process 1000.

In this example, the HEMT is formed on a substrate. The substrate may be a silicon (Si) substrate, engineered substrate (QST), silicon carbide (SiC), gallium nitride (GaN), or may include any other material or combination of materials capable of supporting growth of Group-III nitride materials. In some implementations, the substrate 120 of HEMT 300 corresponds to this substrate.

In step 1005 a nucleation layer is formed on the substrate material. In some implementations, this may have the advantage of reducing lattice mismatch between the substrate and the next layer in the HEMT. The nucleation layer may include any suitable material (e.g., aluminum nitride (AlN)), and may be formed on substrate using any suitable semiconductor growth technique or techniques, such as MOCVD, HVPE, or MBE. In some implementations, the nucleation layer formed on substrate 120 of HEMT 300 corresponds to this step.

In step 1010, a buffer layer is formed on the nucleation layer. In some implementations, the buffer layer is a high resistivity layer which may include doped or undoped layers of Group-III nitride materials. In some implementations, the buffer layer is made from multiple AlGaN layers. The buffer layer may be formed on the nucleation layer using any suitable semiconductor growth technique or techniques, such as MOCVD, HVPE, or MBE. In some implementations, the buffer layer 125 of HEMT 300 corresponds to this step.

In step 1015, a channel layer is formed on the buffer layer. In some implementations, the channel layer is made from doped or undoped Group-III nitride materials. In some implementations, the channel layer is made from GaN. The channel layer may be formed on the buffer layer using any suitable semiconductor growth technique or techniques, such as MOCVD, HVPE, or MBE. In some implementations, the channel layer has a thickness in the range of few hundred nanometers. In some implementations, the channel layer is a high resistance layer which may be made of an unintentionally doped or low doped material. In some implementations, channel layer is or includes an n-type Group-III nitride material. In some implementations, the channel layer 130 of HEMT 300 corresponds to this step.

In step 1020, a barrier layer is formed on the channel layer. The barrier layer may include doped or undoped layers of Group-III nitride materials. The barrier layer may be formed on the channel layer using any suitable semiconductor growth technique or techniques, such as MOCVD, HVPE, or MBE. The thickness and composition of the barrier layer may be selected to obtain positive threshold voltages. In some implementations, the thickness and composition of the barrier layer are selected to provide a larger bandgap than the channel layer typically with AlGaN having an Al mole fraction of 0.18 to 0.23. In some this example, the barrier layer comprises AlGaN with a thickness in the range of 12-25 nm. In some implementations, the barrier layer 135 of HEMT 300 corresponds to this step.

In step 1025, a GaN layer is formed on the barrier layer. In some implementations, the GaN layer includes any suitable Group-III nitride material. In this example, the GaN layer is made of doped GaN (p-type GaN in this example) grown on the barrier layer. In some implementations, the GaN layer has a non-uniform doping concentration (p-type in this example). In some implementations, this non-uniform doping concentration is selected to form a specific electric field and depletion region within the GaN layer.

The GaN layer may be formed on barrier layer 135 using any suitable semiconductor growth technique or techniques, such as MOCVD, HVPE, or MBE. In step 1030, the GaN layer is etched to define a gate region and one or more field plate regions proximate to the gate, but not connected to the gate. In some implementations, a mask layer is defined and a mask and etch process is carried out to make the field plate GaN region substantially thinner than the gate GaN region. In some implementations, the field plate GaN is half to one third of the gate GaN thickness. In some implementations the gate GaN region has a doping concentration in the range of 1×10¹⁶-1×10²⁰ cm³ (e.g., 2-3×10¹⁹ cm³) and a thickness in the range of 50-150 nm. In some implementations, the gate region 315 and field plates 380 and 390 of HEMT 300 correspond to this step.

In step 1035, the HEMT is electrically isolated from other non-active regions of the device or other devices on the substrate. In some implementations, this is performed based on with mesa etch or ion implantation, e.g., of nitrogen or argon, outside the active HEMT.

In step 1040, a dielectric layer is deposited on the structure surface. In some implementations, the dielectric layer is a dielectric material, such as silicon nitride (SiN), silicon dioxide (SiO2), aluminum oxide (Al203), or any other suitable dielectric material. In some implementations, the dielectric layer is deposited over the HEMT to electrically and physically isolate structures of the HEMT from the environment and from each other. In some implementations, the dielectric layer is deposited in several layers. In some implementations, dielectric 340 of HEMT 300 corresponds to this step.

In step 1045, metal source and drain electrodes are formed making ohmic contact with the barrier layer after masking and etching the dielectric layer. In some implementations, pre and/or post deposition treatment and annealing processes may be applied. In some implementations, source contact 305 and drain contact 310 of HEMT 300 correspond to this step.

In step 1050, a metal gate electrode is formed on the GaN gate region. In some implementations, the metal gate electrode is a Schottky or Ohmic gate metal contact formed the GaN gate region after masking and etching the dielectric layer. In some implementations, pre and/or post deposition treatment and annealing processes may be applied. In some implementations, gate contact 350 of HEMT 300 corresponds to this step. It is noted that the sequence of forming source, drain, and gate metal contacts (e.g., steps 1045 and 1050) are reversible in some implementations.

In step 1055, one or more field plates are formed on the barrier layer. In some implementations, the field plates include any suitable Group-III nitride material, such as GaN or AlGaN. For example, in some implementations, the field plates are made of doped GaN (p-type GaN in this example) grown on the barrier layer. In some implementations, the field plates have a non-uniform doping concentration. In some implementations, this non-uniform doping concentration is selected to form a specific electric field and depletion region within the field plate.

In some implementations, the field plates may be formed on the barrier layer using any suitable semiconductor growth technique or techniques, such as MOCVD, HVPE, or MBE. In some implementations, the field plates are made from GaN (e.g., p-type GaN). In some implementations, the field plates shield the gate region and/or gate contact from electric fields (e.g., high electric fields, such as fields having a strength above a threshold field strength). In some implementations, the field plates are formed from a same layer of GaN (e.g., P-GAN) material (e.g., by patterning and/or etching) used to form the GaN gate region.

In some implementations, the field plates have a doping concentration that is different from a doping concentration of the gate region. In some implementations, the field plates are doped with a dopant material that is different from a dopant material of the gate region. In some implementations, the field plates have a doping concentration in the range of 1×10¹⁶-1×10²⁰ cm³ (e.g., 2-3×10¹⁹ cm³). In some implementations, the field plates are substantially thinner than the gate region. In some implementations, the field plates have a thickness of or of approximately one-third to one-half that of the gate region. In some implementations, the field plates have dimensions (e.g., length, height, width) that differ from those of the gate region. In some implementations, the reduced thickness or different dimensions of the field plates as compared with the gate region is achieved by applying a mask and etch process to the field plates.

In some implementations, field plates 380 and 390 of HEMT 300 correspond to this step.

In step 1060 one or more of the field plates are electrically connected to a voltage reference. In some implementations, some of the field plates are electrically connected to or in communication with source contact 305 via metal, or otherwise held at the same potential as source contact 305, and other field plates are floating and not connected to a fixed voltage source or reference. In some implementations, a field plate from among a plurality of field plates that is closest to the drain region is floating, and one or more of the other field plates are electrically connected to a voltage reference, such as the source or ground. In some implementations, there is only one field plate, which is floating. In some implementations, the field plate closest to the gate is at ground (i.e., source potential) e.g., to avoid the field plate from acquiring a potential that is too high.

In step 1065, a dielectric layer (e.g., SiN, SiO2, or Al2O3) is deposited over the barrier region between the gate and source, between the gate and field plates, between the field plates and the drain, and partially on the source and drain. In some implementations, the dielectric layer electrically and physically isolates structures of the HEMT from the environment and from each other. In some implementations, the dielectric layer is deposited in several layers. In some implementations, dielectric 340 of HEMT 300 corresponds to this step.

It should be understood that many variations are possible based on the disclosure herein. Although features and elements are described above in particular combinations, each feature or element can be used alone without the other features and elements or in various combinations with or without other features and elements.

1. A high electron mobility transistor (HEMT), comprising:
a source disposed on a surface;
a drain disposed on the surface;
a gate disposed on the surface between the source and the drain; and
a first field plate disposed on the surface between the gate and the drain;
wherein the first field plate comprises a doping concentration or doping material that is configured to minimize an increase in an on-resistance of the HEMT.

2. The HEMT of claim 1, wherein, the first field plate comprises doped gallium nitride (GaN).

3. The HEMT of claim 1, wherein the first field plate is at a floating voltage.

4. The HEMT of claim 1, wherein the first field plate is not electrically connected to a voltage source.

5. The HEMT of claim 1, further comprising a second field plate disposed on the surface between the gate and the first field plate.

6. The HEMT of claim 5, wherein the second field plate is electrically connected to a voltage source.

7. The HEMT of claim 5, wherein the second field plate is electrically connected to the source.

8. The HEMT of claim 1, wherein the first field plate comprises GaN and has a different concentration of dopant, a different type of dopant, or a different dopant material, than the gate.

9. The HEMT of claim 1, wherein the first field plate comprises a geometry, and/or position that is configured to minimize the increase in the on-resistance of the HEMT.

10. The HEMT of claim 1, wherein the first field plate is continuous.

11. The HEMT of claim 1, wherein the first field plate extends continuously between and parallel to the source and the drain, such that any path from the source to the drain passes under, through, or over the first field plate.

12. The HEMT of claim 1, wherein the first field plate extends continuously beyond an entire width of the surface between the source and the drain.

13. The HEMT of claim 1, wherein the first field plate is closer to the gate than to the drain.

14. The HEMT of claim 1, wherein the first field plate comprises a p-type doped GaN (P-GaN).

15. The HEMT of claim 1, wherein the first field plate comprises a p-type doped aluminum GaN (AlGaN) or an n-type doped AlGaN.

16. A method for manufacturing a high electron mobility transistor (HEMT), the method comprising:
depositing a gate material on a surface between a source and a drain; and
depositing a first field plate material on the surface between the gate material and the drain;
wherein the first field plate material comprises a doping concentration or doping material that is configured to minimize an increase in an on-resistance of the HEMT.

17. The method of claim 16, wherein the gate material and the first field plate material comprise doped gallium nitride (GaN).

18. The method of claim 16, wherein the first field plate material extends continuously across the surface between the source and the drain, such that any path from the source to the drain passes under, through, or over the first field plate material.

19. The method of claim 16, wherein the first field plate material comprises a p-type doped GaN (P-GaN).

20. The method of claim 16, wherein the first field plate material comprises a p-type doped aluminum GaN (AlGaN) or an n-type doped AlGaN.
